(19) United States
(12) Patent Application Publication
(10) Pub. No.: US 2013/0257830 A1
(43) Pub. Date: Oct. 3, 2013

(54) OUTPUT DRIVER, ELECTRICAL DEVICE HAVING THE OUTPUT DRIVER, AND METHOD OF EVALUATING THE OUTPUT DRIVER

(71) Applicant: LAPIS SEMICONDUCTOR CO., LTD., Tokyo (JP)

(72) Inventor: Daisuke KADOTA, Tokyo (JP)

(73) Assignee: LAPIS SEMICONDUCTOR CO., LTD., Tokyo (JP)

(21) Appl. No.: 13/778,563

(22) Filed: Feb. 27, 2013

(30) Foreign Application Priority Data
Mar. 27, 2012 (JP) 2012-071076

(51) Int. Cl. G09G 3/00; H03K 17/00

(52) U.S. Cl. CPC G09G 3/006; H03K 17/00
USPC 345/204; 327/108

(57) ABSTRACT

An output driver includes a data processing unit configured to perform a data processing on an input signal to generate processing result data; a D/A (Digital-to-Analog) conversion unit configured to apply D/A conversion on the processing result data to generate an analog signal; an output amplifier configured to amplify the analog signal to obtain an amplified analog signal as an output signal; a comparing unit configured to compare the processing result data with expected value data to obtain and output comparison result data; and an output control unit configured to select the comparison result data as the output signal instead of the amplified analog signal according to a comparison output selection signal.

### BACKGROUND OF THE INVENTION AND RELATED ART STATEMENT

The present invention relates to an output driver capable of converting input digital data to an analog signal and outputting the analog signal. Further, the present invention relates to an electrical device having the output driver and a method of evaluating the output driver.

In general, a semiconductor device is provided for controlling a display panel of, for example, an automobile navigation system and the like. In the semiconductor device, an internal logic circuit is provided for processing an input signal to obtain digital data for controlling the display panel. Further, a conventional output driver is provided for converting the digital data to an analog signal, and for outputting the analog signal.

Patent Reference has disclosed a configuration for evaluating a processing result of the internal logic circuit. In the configuration disclosed in Patent Reference, a selector unit is provided on a front stage relative to a D/A (digital-to-analog) converter, so that it is possible to output selectively between the processed data from the internal login circuit and evaluation result data during the evaluation.
Patent Reference: Japanese Patent Publication No. 07-209385

In the conventional output driver disclosed in Patent Reference, the selector unit is provided on the front stage relative to the D/A (digital-to-analog) converter as described above. When an output amplifier is provided on a later stage relative to the D/A converter in the conventional output driver disclosed in Patent Reference, the following problems may occur.

In the conventional output driver disclosed in Patent Reference, it is necessary to configure the conventional output driver capable of receiving both the processed data and the evaluation result data in a normal operation, thereby increasing a circuit size of the conventional output driver. Further, when the conventional output driver is configured to be capable of receiving both the processed data and the evaluation result data, the output accuracy tends to be deteriorated in the normal operation.

In view of the problems described above, an object of the present invention is to provide an output driver capable of performing an evaluation test without increasing a circuit size or deteriorating the output accuracy. Further, an object of the present invention is to provide an electrical device having the output driver and a method of evaluating the output driver without increasing a circuit size or deteriorating the output accuracy.

Further objects and vantages of the invention will be apparent from the following description of the invention.

### SUMMARY OF THE INVENTION

In order to attain the objects described above, according to a first aspect of the present invention, an output driver includes a data processing unit; a D/A (Digital-to-Analog) conversion unit; an output amplifier; a comparing unit; and an output control unit.

According to the first aspect of the present invention, in the output driver, the data processing unit is configured to perform a data processing on an input signal to generate processing result data. The D/A conversion unit is configured to apply D/A conversion on the processing result data to generate an analog signal. The output amplifier is configured to amplify the analog signal to obtain an amplified analog signal as an output signal. Further, the comparing unit is configured to compare the processing result data with expected value data to obtain and output comparison result data. The output control unit is configured to select the comparison result data as the output signal instead of the amplified analog signal according to a comparison output selection signal.

According to a second aspect of the present invention, an electric device includes a display unit and a semiconductor device for controlling the display unit.

According to the second aspect of the present invention, the semiconductor device includes a data processing unit; a D/A (Digital-to-Analog) conversion unit; an output amplifier; a comparing unit; and an output control unit.

According to the second aspect of the present invention, in the output driver, the data processing unit is configured to perform a data processing on an input signal to generate processing result data. The D/A conversion unit is configured to apply D/A conversion on the processing result data to generate an analog signal. The output amplifier is configured to amplify the analog signal to obtain an amplified analog signal as an output signal. Further, the comparing unit is configured to compare the processing result data with expected value data to obtain and output comparison result data. The output control unit is configured to select the comparison result data as the output signal instead of the amplified analog signal according to a comparison output selection signal.

According to a third aspect of the present invention, a method is used for evaluating an output driver.

According to the third aspect of the present invention, in the method of evaluating the output driver, the output driver includes a data processing unit; a D/A (Digital-to-Analog) conversion unit; and an output amplifier.

According to the third aspect of the present invention, the method of evaluating the output driver includes a comparing step and an output control step. In the comparison step, the processing result data is compared with expected value data to obtain and output comparison result data. In the output control step, the comparison result data is selected as the output signal instead of the amplified analog signal according to a comparison output selection signal.

In the present invention, it is possible to provide the output driver capable of performing an evaluation test without increasing a circuit size or deteriorating the output accuracy. Further, it is possible to provide the electrical device having the output driver and the method of evaluating the output driver without increasing a circuit size or deteriorating the output accuracy.

### BRIEF DESCRIPTION OF THE DRAWINGS

FIG. 1 is a block diagram showing a configuration of an output driver according to a first embodiment of the present invention;

FIG. 2 is a circuit diagram showing a selector unit of the output driver according to the first embodiment of the present invention;

FIG. 3 is a block diagram showing a configuration of an output driver according to a second embodiment of the present invention;

FIG. 4 is a block diagram showing a configuration of an output driver according to a third embodiment of the present invention; and

FIG. 5 is a block diagram showing a configuration of an electric device having a semiconductor device including an output driver according to a fourth embodiment of the present invention.

### DETAILED DESCRIPTION OF PREFERRED EMBODIMENTS

Hereunder, preferred embodiments of the present invention will be explained with reference to the accompanying drawings.

### First Embodiment

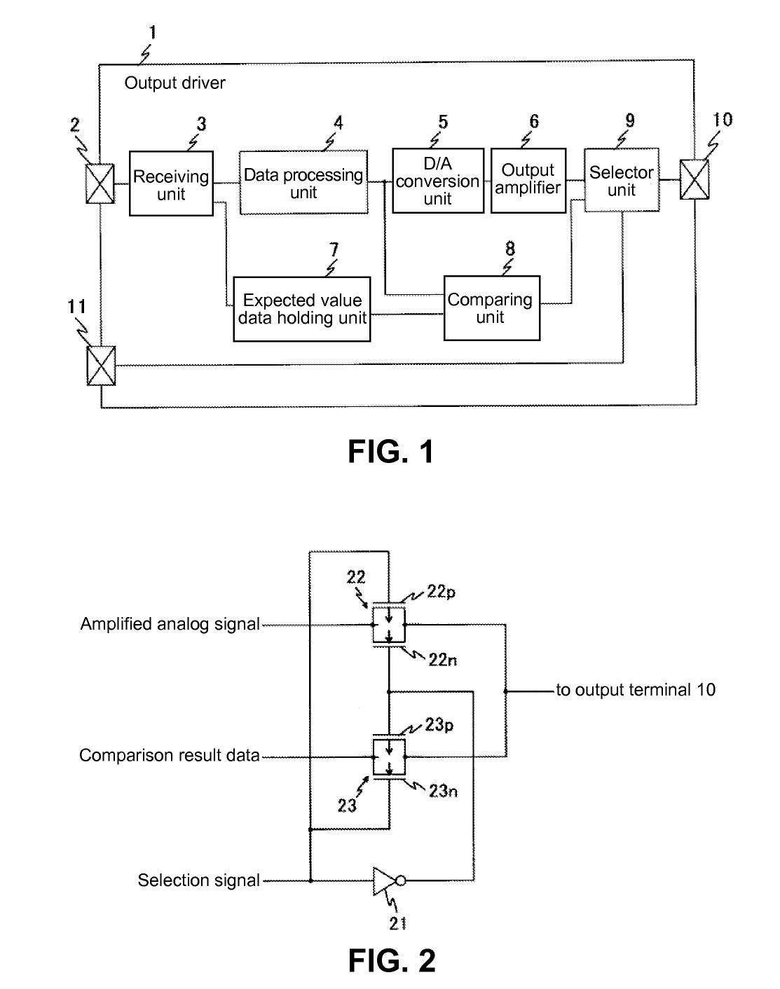

A first embodiment of the present invention will be explained. FIG. 1 is a block diagram showing a configuration of an output driver 1 according to the first embodiment of the present invention.

As shown in FIG. 1, the output driver 1 includes a receiving unit 3 for receiving a control signal input into a signal input terminal 2, so that the receiving unit 3 supplies the control signal to a data processing unit 4 arranged at a later stage thereof. The control signal includes, for example, a data signal and a clock signal for controlling, for example, a display panel (not shown in FIG. 1) of an automobile navigation system and the like.

In the first embodiment, the receiving unit 3 is configured to receive expected value data input into the signal input terminal 2, and to supply the expected value data to an expected value data holding unit 7. The expected data is data to be compared with digital data (hereunder, referred to as processing result data) that is obtained as a result of data processing performed with the data processing unit 4. Further, the expected value data is input into the signal input terminal 2 accompanying with an identification mark indicating that the data is the expected value data. Accordingly, the receiving unit 3 is configured to determine that the data input into the signal input terminal 2 is the expected value data according to the identification mark included therein.

In the first embodiment, the data processing unit 4 is configured to apply a specific data processing on the control signal supplied from the receiving unit 3 to obtain the processing result data, so that the data processing unit 4 outputs the processing result data.

As shown in FIG. 1, the output driver 1 further includes a D/A (Digital-to-Analog) conversion unit 5. The D/A conversion unit 5 is configured to apply a digital-to-analog conversion processing on the processing result data output from the data processing unit 4 to generate an analog signal.

As shown in FIG. 1, the output driver 1 further includes an output amplifier 6. The output amplifier 6 is configured to amplify the analog signal with the D/A conversion performed thereon to generate an amplified analog signal

In the first embodiment, the expected value data holding unit 7 is configured to hold the expected value data supplied from the receiving unit 3. The expected value data holding unit 7 is formed, for example, a register.

As shown in FIG. 1, the output driver 1 further includes a comparing unit 8. The comparing unit 8 is configured to compare the processing result data output from the data processing unit 4 with the expected value data held in the expected value data holding unit 7, so that the comparing unit 8 outputs a comparison result. More specifically, when the processing result data matches the expected value data, the comparing unit 8 outputs data having a high “H” level. When the processing result data does not match the expected value data, the comparing unit 8 outputs data having a low “L” level. In the following description, the data output from the comparing unit 8 is referred to as comparison result data.

As shown in FIG. 1, the output driver 1 further includes a selector unit 9. The selector unit 9 is configured to select one of the amplified analog signal output from the output amplifier 6 and the comparison result data output from the comparing unit 8, so that the selector unit 9 outputs the selected one from an output terminal 10 according to a selection signal input into a selection signal input terminal 11.

More specifically, in the first embodiment, when the selection signal has a low “L” level, that is, a normal mode, the selector unit 9 is configured to select the amplified analog signal. When the selection signal has a high “H” level, that is, an evaluation mode, the selector unit 9 is configured to select the comparison result data. When the selection signal indicates the evaluation mode, the comparing unit 8 may be configured to operate. In the following description, the selection signal with the low “L” level is referred to as an amplifier output selection signal, and the selection signal with the high “H” level is referred to as a comparison output selection signal. Further, the selector unit 9 is referred to also as an output control unit.

In the first embodiment, it may be configured such that a microprocessor (for example, a control circuit 43 shown in FIG. 5) executes a program stored in a recording medium such as an ROM (for example, a storage unit 42 shown in FIG. 5), so that the functions of the components of the output driver 1 are realized.

FIG. 2 is a circuit diagram showing the selector unit 9 of the output driver 1 according to the first embodiment of the present invention.

As shown in FIG. 2, the selector unit 9 includes an inverter 21. The inverter 21 is configured to receive the selection signal from the selection signal input terminal 11, and output a level-inverted signal of the selection signal. The selection signal is supplied from, for example, a control circuit such as a CPU (for example, the control circuit 43 shown in FIG. 5) disposed in, for example, an automobile navigation system.

As shown in FIG. 2, the selector unit 9 further includes a switch 22. The switch 22 is formed of a P-channel MOSFET 22p and an N-channel MOSFET 22n. The P-channel MOSFET 22p and the N-channel MOSFET 22n are mutually connected through drain terminals and source terminals thereof. The amplified analog signal from the output amplifier 6 is input to the source terminals of the P-channel MOSFET 22p and the N-channel MOSFET 22n. The drain terminals of the P-channel MOSFET 22p and the N-channel MOSFET 22n are connected to the output terminal 10 (refer to FIG. 1). The selection signal is input into a gate terminal of the P-channel MOSFET 22p, and the inverted signal of the selection signal is input into a gate terminal of the N-channel MOSFET 22n.

As shown in FIG. 2, the selector unit 9 further includes a switch 23. The switch 23 is formed of a P-channel MOSFET 23p and an N-channel MOSFET 23n. The P-channel MOSFET 23p and the N-channel MOSFET 23n are mutually connected through drain terminals and source terminals thereof. The comparison result data from the comparing unit 8 is input to the source terminals of the P-channel MOSFET 23p and the N-channel MOSFET 23n. The drain terminals of the P-channel MOSFET 23p and the N-channel MOSFET 23n are connected to the output terminal 10 (refer to FIG. 1). The inverted signal of the selection signal is input into a gate terminal of the P-channel MOSFET 23p, and the selection signal is input into a gate terminal of the N-channel MOSFET 23n.

In the first embodiment, when the selection signal with the low “L” level is supplied from the selection signal input terminal 11, that is, in the normal mode, only the switch 22 is turned on, so that the amplified analog signal from the output amplifier 6 is output through the output terminal 10. When the selection signal with the high “H” level is supplied from the selection signal input terminal 11, that is, in the evaluation mode, only the switch 23 is turned on, so that the comparison result data from the comparing unit 8 is output through the output terminal 10.

An operation of the output driver 1 in the first embodiment will be explained next with reference to FIG. 1. First, the receiving unit 3 receives the control signal input into the signal input terminal 2, and supplies the control signal to the data processing unit 4 disposed at the later stage thereof.

In the next step, the receiving unit 3 receives the expected value data input into the signal input terminal 2, and supplies the expected value data to the expected value data holding unit 7. In this step, the receiving unit 3 determines that the data input into the signal input terminal 2 is the expected value data according to the identification mark accompanied with the expected value data. The expected value data is the data representing an expected value to be obtained when the data processing unit 4 performs the data processing on the control signal input previously. The expected value data may be equal to the control signal. Then, the expected value data holding unit 7 holds the expected value data supplied from the receiving unit 3. When it is necessary to process the expected value data (for example, a size of the expected value data is changed, or a part of the control signal is used as the expected value data), the expected value data may be held in the expected value data holding unit 7 after the expected value data is processed.

In the first embodiment, the data processing unit 4 performs the data processing on the control signal supplied from the receiving unit 3 to obtain the processing result data, and outputs the processing result data. Further, the D/A conversion unit 5 performs the digital-to-analog conversion processing on the processing result data output from the data processing unit 4 to generate the analog signal. Further, the output amplifier 6 amplifies the analog signal generated with the D/A conversion unit 5 to generate the amplified analog signal.

In the first embodiment, the comparing unit 8 compares the processing result data output from the data processing unit 4 with the expected value data held in the expected value data holding unit 7 to obtain the comparison result data, so that the comparing unit 8 outputs the comparison result data. More specifically, when the processing result data matches the expected value data, the comparing unit 8 outputs the comparison result data having the high “H” level. When the processing result data does not match the expected value data, the comparing unit 8 outputs the comparison result data having the low “L” level.

In the first embodiment, when the selection signal input into the selection signal input terminal 11 has the low “L” level, that is, the normal mode, the selector unit 9 selects the amplified analog signal. When the selection signal has the high “H” level input into the selection signal input terminal 11, that is, the evaluation mode, the selector unit 9 selects the comparison result data. Accordingly, the selector unit 9 outputs the amplified analog signal or the comparison result data thus selected through the output terminal 10.

As described above, in the output driver 1 in the first embodiment, when it is the normal mode, the amplified analog signal is output. When it is the evaluation mode, the comparison result data is output. Accordingly, when an operator determines whether the comparison result data output from the output terminal 10 has the high “H” level or the low “L” level, it is possible to determine whether the data processing unit 4 performs the data processing properly. Accordingly, it is possible to determine that the data processing unit 4 performs the data processing erroneously, or the amplification level of the output amplifier 6 is excessive or insufficient.

Further, in the output driver 1 in the first embodiment, the selector unit 9 is provided for outputting the amplified analog signal or the comparison result data thus selected through the one single component, i.e., the output terminal 10. With the configuration, it is not necessary to provide another output terminal specific for the evaluation, thereby making it possible to perform the evaluation with a smaller number of the terminals.

Further, in the output driver 1 in the first embodiment, the selector unit 9 is disposed at the later stage relative to the output amplifier 6. With the configuration, the output amplifier 6 is provided for amplifying only the analog signal as the amplification subject (that is, the comparison result data is not the amplification subject). Accordingly, it is possible to prevent the circuit size of the output amplifier 6 from increasing. Further, the output amplifier 6 is provided for amplifying only the analog signal, so that it is possible to prevent the output accuracy of the amplified analog signal from deteriorating in the normal mode. Accordingly, in the output driver 1 in the first embodiment, it is possible to perform the evaluation without increasing the circuit size and deteriorating the output accuracy in the normal mode.

### Second Embodiment

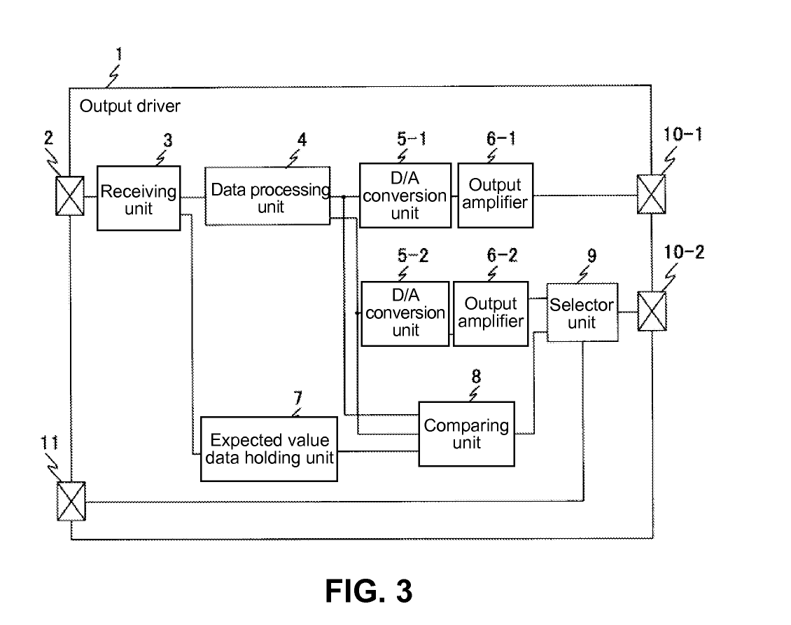

A second embodiment of the present invention will be explained next. FIG. 3 is a block diagram showing a configuration of the output driver 1 according to the second embodiment of the present invention.

As shown in FIG. 3, the output driver 1 includes a pair of D/A (Digital-to-Analog) conversion units 5-1 and 5-2, and a pair of output amplifiers 6-1 and 6-2. The output amplifier 6-1 is connected to an output terminal 10-1, and the selector unit 9 is connected to an output terminal 10-2.

In the second embodiment, the data processing unit 4 is configured to output the processing result data with a plurality of bits, and the comparing unit 8 is configured to compare simultaneously with respect to each of the bits of the processing result data. Further, the expected value data holding unit 7 is configured to hold the expected value data with a plurality of bits corresponding to each of the bits of the processing result data. More specifically, the output driver 1 has the configuration, in which the expected value data holding unit 7 and the comparing unit 8 are shared with respect to the bits of the processing result data. The comparison unit 8 is configured to compare each of the bits of the processing result data with each of the bits of the expected value data one by one.

In the second embodiment, with the configuration described above having the combination of the expected value data holding unit 7 and the comparing unit 8, it is possible to collectively compare with respect to the bits constituting the processing result data. Accordingly, it is possible to reduce the circuit size by the amount that the comparing unit 8 is shared.

### Third Embodiment

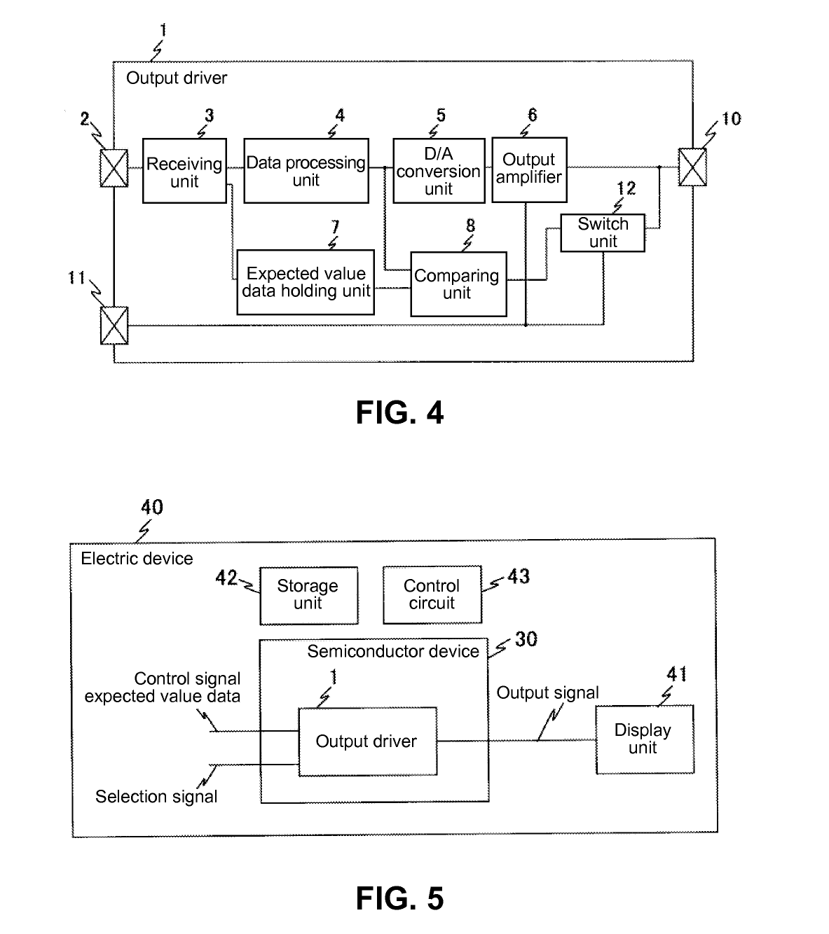

A third embodiment of the present invention will be explained next. FIG. 4 is a block diagram showing a configuration of the output driver 1 according to the third embodiment of the present invention. In the following description, a difference from the first embodiment will be mainly explained.

As shown in FIG. 4, the output driver 1 includes a switch unit 12 as an output control unit. An output terminal of the output amplifier 6 is directly connected to the output terminal 10. In the third embodiment, when the selection signal supplied through the selection signal input terminal 11 is the low “L” level, that is, the normal mode, the output amplifier 6 outputs the amplified analog signal. When the selection signal is the high “H” level supplied through the selection signal input terminal 11, that is, the evaluation mode, the output amplifier 6 stops outputting the amplified analog signal.

In the third embodiment, an output terminal of the comparing unit 8 is connected to the output terminal 10 through the switch unit 12. When the selection signal supplied through the selection signal input terminal 11 is the low “L” level, that is, the normal mode, the switch unit 12 is turned off. In this case, the comparison result data is not output. When the selection signal supplied through the selection signal input terminal 11 is the high “H” level, that is, the evaluation mode, the switch unit 12 is turned on. In this case, the comparison result data is output through the output terminal 10.

In the third embodiment, the signal level of the selection signal supplied to the output amplifier 6 is at the same level as the signal level of the selection signal supplied to the switch unit 12. More specifically, when the selection signal having the high “H” level is supplied to the output amplifier 6, the selection signal having the high “H” level is supplied to the switch unit 12. Similarly, when the selection signal having the low “L” level is supplied to the output amplifier 6, the selection signal having the low “L” level is supplied to the switch unit 12.

As described above, in the third embodiment, the output driver 1 has the configuration capable of performing the evaluation. Further, the output terminal 10 is provided as the only one single component for outputting the evaluation result, and the output terminal of the output amplifier 6 is directly connected to the output terminal 10. Accordingly, the amplified analog signal output through the output terminal 10 in the normal mode is not significantly influenced by the configuration for performing the evaluation. As a result, it is possible to maintain the output accuracy of the amplified analog signal in the normal mode, as well as to output the comparison result data having the logic value of the high “H” level or the low “L” level.

### Fourth Embodiment

A fourth embodiment of the present invention will be explained next. FIG. 5 is a block diagram showing a configuration of an electric device 40 having a semiconductor device 30 including the output driver 1 according to the fourth embodiment of the present invention. The electric device 40 may include, for example, an automobile navigation system.

As shown in FIG. 5, the electric device 40 includes a display unit 41, and the semiconductor device 30 is configured to control the display unit 41. Further, the electric device 40 includes the storage unit 42 as a storage device such as a hard disk and the like for storing display data. The display data is input into the signal input terminal 2 of the output driver 1 (refer to FIG. 1).

In the fourth embodiment, the output driver 1 is configured to supply a display control signal to the display unit 41 according to the display data. Further, the electric device 40 includes the control circuit 43 capable of controlling various components of the electric device 40 and supplying various data and various control signals such as the selection signal and the like to the semiconductor device 30. The control circuit 43 is formed of, for example, a CPU (Central Processing Unit). It is noted that the electric device 40 is not limited to the configuration described above, and may include other components. In addition to the automobile navigation system, the electric device 40 may be other automobile devices or other electrical devices.

The disclosure of Japanese Patent Application No. 2012-071076, filed on Mar. 27, 2012, is incorporated in the application by reference.

While the invention has been explained with reference to the specific embodiments of the invention, the explanation is illustrative and the invention is limited only by the appended claims.

What is claimed is:

1. An output driver, comprising:
a data processing unit configured to perform a data processing on an input signal to generate processing result data;
a D/A (Digital-to-Analog) conversion unit configured to apply D/A conversion on the processing result data to generate an analog signal;
an output amplifier configured to amplify the analog signal to obtain an amplified analog signal as an output signal;
a comparing unit configured to compare the processing result data with expected value data to obtain and output comparison result data; and
an output control unit configured to select the comparison result data as the output signal instead of the amplified analog signal according to a comparison output selection signal.

2. The output driver according to claim 1, further comprising a first output terminal directly connected to a second output terminal of the output amplifier,
wherein said output amplifier is configured to output the output signal through the first output terminal only when the output control unit does not receive the comparison output selection signal,
said output control unit is disposed between the first output terminal and the second output terminal, and
said output control unit is formed of a switch unit for supplying the comparison result data to the first output terminal as the output signal according to the comparison output selection signal.

3. The output driver according to claim 1, wherein said output control unit is formed of a selector unit for receiving the amplified analog signal and the comparison result data, and for selecting the comparison result data as the output signal according to the comparison output selection signal.

4. The output driver according to claim 1, wherein said data processing unit is configured to generate the processing result data with a plurality of bits, and
said comparing unit is configured to compare each of the bits of the processing result data with each of bits of the expected value data one by one to output the comparison result data.

5. The output driver according to claim 1, further comprising an expected value data holding unit configured to hold the expected value data input externally.

6. An electrical device, comprising:
a display unit; and
a semiconductor device configured to control the display unit,
wherein said semiconductor device includes:
a data processing unit configured to perform a data processing on an input signal to generate processing result data;
a D/A (Digital-to-Analog) conversion unit configured to apply D/A conversion on the processing result data to generate an analog signal;
an output amplifier configured to amplify the analog signal to obtain an amplified analog signal as an output signal;
a comparing unit configured to compare the processing result data with expected value data to obtain and output comparison result data; and
an output control unit configured to supply the comparison result data as the output signal to the display unit instead of the amplified analog signal according to a comparison output selection signal.

7. A method of evaluating an output driver that includes a data processing unit configured to perform a data processing on an input signal to generate processing result data; a D/A (Digital-to-Analog) conversion unit configured to apply D/A conversion on the processing result data to generate an analog signal; and an output amplifier configured to amplify the analog signal to obtain an amplified analog signal as an output signal,
said method comprising the steps of:
a comparing step of comparing the processing result data with expected value data to obtain and output comparison result data; and
an output control step of selecting the comparison result data as the output signal instead of the amplified analog signal according to a comparison output selection signal.

8. The method of evaluating an output driver according to claim 7, wherein, in the comparing step, said processing result data is compared with the expected value data so that a first level signal is output as the comparison result data when the processing result data matches the expected value data, and a second level signal is output as the comparison result data when the processing result data does not match the expected value data.

9. The method of evaluating an output driver according to claim 7, wherein, in the output control step, said comparison result data is selected as the output signal when the comparison output selection signal indicates an evaluate mode, and the amplified analog signal is selected as the output signal when the comparison output selection signal indicates a normal mode.
